(19) United States
(12) Patent Application Publication
(10) Pub. No.: US 2025/0343125 A1
(43) Pub. Date: Nov. 6, 2025

(54) SEMICONDUCTOR STRUCTURES AND MANUFACTURING METHOD OF THE SAME

(71) Applicant: Taiwan Semiconductor Manufacturing Company, Ltd., Hsinchu (TW)

(72) Inventors: Po-Ching Wu, Hsinchu (TW); An-Jhih Su, Taoyuan City (TW); Meng-Tsan Lee, Hsinchu (TW); Hsuan-Ting Kuo, Taichung City (TW); Hsiu-Jen Lin, Hsinchu County (TW)

(73) Assignee: Taiwan Semiconductor Manufacturing Company, Ltd., Hsinchu (TW)

(21) Appl. No.: 18/652,772

(22) Filed: May 1, 2024

(51) Int. Cl. H01L 23/498; H01L 21/48; H01L 21/56; H01L 23/00; H01L 23/15; H01L 23/48; H01L 23/538; H01L 25/10

(52) U.S. Cl. CPC H01L 23/49833; H01L 21/486; H01L 21/56; H01L 23/15; H01L 23/481; H01L 23/5389; H01L 24/16; H01L 24/32; H01L 24/73; H01L 25/105; H01L 2224/16225; H01L 2224/32225; H01L 2224/73204; H01L 2225/1058; H01L 2924/1815

(57) ABSTRACT

A package structure and manufacturing methods thereof are described. The package structure includes a core substrate. The package structure includes a build up structure disposed on the core substrate. The build up structure includes a recess in the build up structure. The package structure includes a semiconductor die disposed on the build up structure and over the core substrate. The package structure includes a bridge die disposed in the recess of the build up structure and between the semiconductor die and the core substrate. The bridge die includes first connectors and second connectors respectively disposed on two opposing surfaces of the bridge die and conductive through vias penetrating the bridge die and electrically connected with the first and second connector. The bridge die is electrically connected with the semiconductor die and the core substrate respectively through the first connectors and second connectors.

### BACKGROUND

Integration of multiple semiconductor devices and electronic components requires advanced packaging and assembling techniques.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A though FIG. 1E are schematic cross-sectional views illustrating structures produced at various stages of a method of forming an electronic component in accordance with some embodiments of the present disclosure.

FIG. 1F is a schematic cross-sectional view of an exemplary structure of an electronic component in accordance with another embodiment of the present disclosure.

FIG. 2A though FIG. 2D are schematic plane views illustrating intermediate stages of a method of forming a package substrate with an electronic component therein, in accordance with some embodiments of the present disclosure.

FIG. 3A through 3H are schematic cross-sectional views illustrating structures produced at various stages of a manufacturing process of a semiconductor package, in accordance with some embodiments of the present disclosure.

### DETAILED DESCRIPTION

The present disclosure relates generally to packaging devices and methods of manufacturing, for semiconductor devices.

It is to be understood that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the performance of a first process before a second process in the description that follows may include embodiments in which the second process is performed immediately after the first process, and may also include embodiments in which additional processes may be performed between the first and second processes. Various features may be arbitrarily drawn in different scales for the sake of simplicity and clarity. Furthermore, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In some embodiments, the manufacturing method is part of a package manufacturing process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

Throughout the various views and illustrative embodiments, like reference numbers are used to designate like elements.

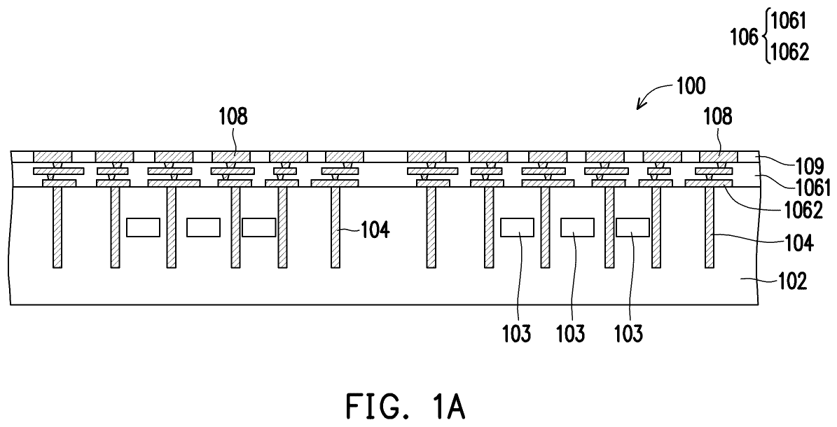

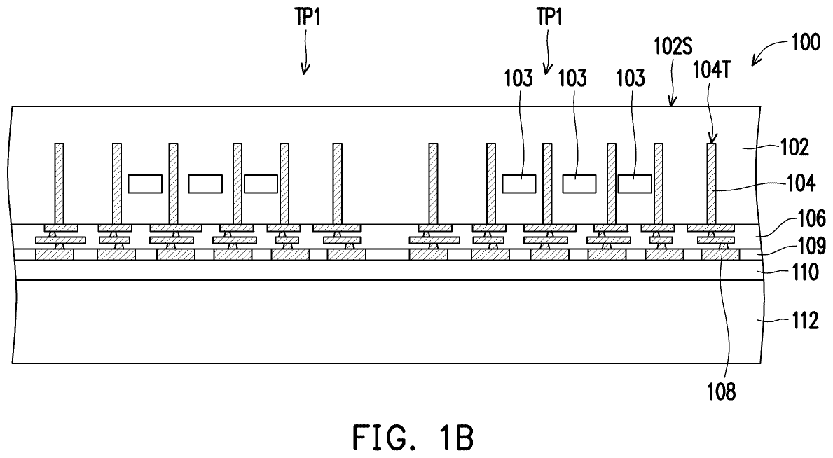

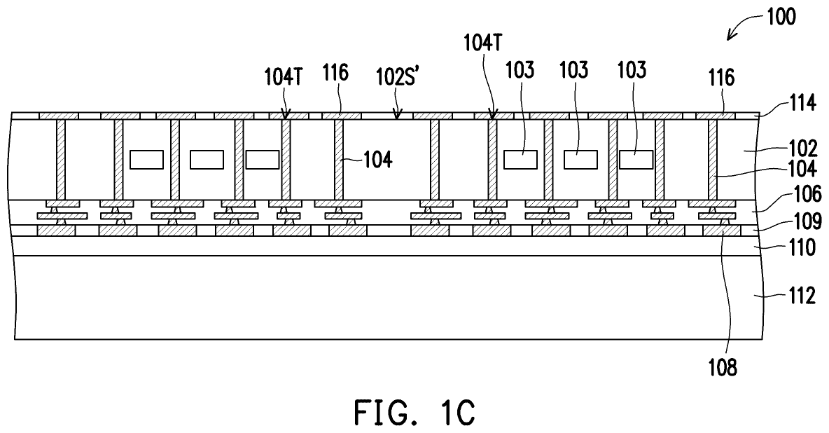

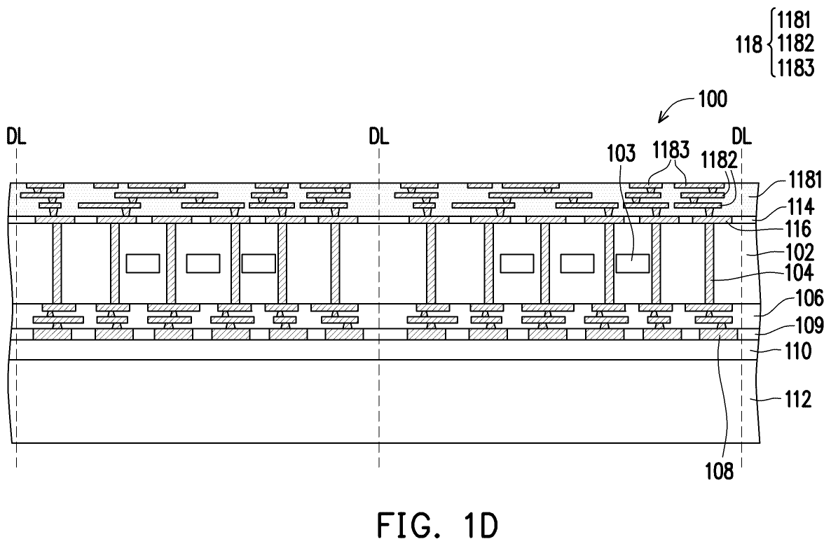

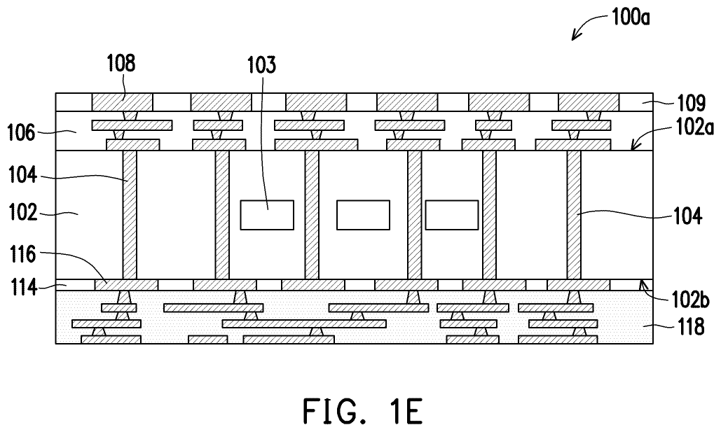

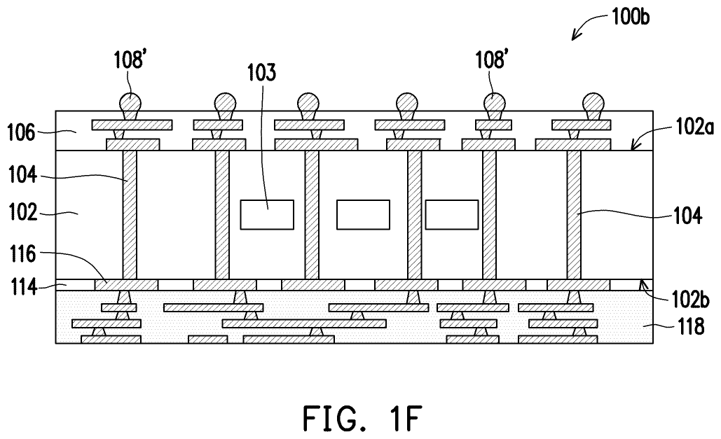

FIG. 1A though FIG. 1E are schematic cross-sectional views illustrating structures produced at various stages of a method of forming an electronic component 100a having double-sided electrical connectivity in a package substrate, in accordance with some embodiments of the present disclosure.

Referring to FIG. 1A, a structure 100 including a substrate 102 and an interconnect structure 106 disposed thereon is provided. In some embodiment, the substrate 102 includes one or more device layers 103 formed therein. In some embodiments, the interconnect structure 106 includes metallization patterns 1062 embedded in a dielectric material 1061. In some embodiments, the structure 100 is provided in a form of a wafer, and the substrate 102 is provided as a portion of a semiconductor wafer such as a silicon wafer. In some embodiments, the structure 100 provided in a wafer form may include a plurality of die units (only two are shown in FIG. 1A), and it is understood that the plurality of die units may include the same type of dies or different type of dies. In some embodiments, the substrate 102 is or includes a bulk mono-crystalline semiconductor substrate, a layer of silicon on a silicon bulk wafer, a layer of a silicon-on-insulator (SOI) wafer, or a layer of a germanium-on-insulator (GOI) wafer. In other embodiments, other semiconductors, such as silicon germanium, germanium, gallium arsenide, indium arsenide, indium gallium arsenide, indium antimonide or others, can be used with the wafer.

In some embodiments, the device layer(s) 103 includes semiconductor devices, and the semiconductor devices may include active devices, passive devices or the combinations thereof. In certain embodiments, the semiconductor devices in the substrate 102 may be formed using front-end-of-line (FEOL) processes. In some embodiments, the device layer(s) 103 includes integrated passive devices (IPDs). For example, the semiconductor devices include devices such as capacitors, resistors, diodes, photo-diodes, sensors or fuses, and further include transistors, memories or power devices, which are formed by any suitable formation methods. Referring to FIG. 1A, the interconnect structure 106 formed over the substrate 102 is electrically connected to the semiconductor devices in the device layers 103. In some embodiment, the substrate 102 may further include a through substrate via (TSV) 104 disposed within the semiconductor substrate 102 for assisting dual-side electrical connection. In some embodiments, an isolation layer 109 is formed on the interconnect structure 106 and a plurality of connectors 108 is formed in the isolation layer 109 and disposed on the metallization patterns 1062. In some embodiments, the connectors 108 include conductive posts, conductive pillars, conductive vias, or the like. In some embodiments, a material of the TSV 104 includes one or more metallic material such as copper, titanium, tungsten, aluminum, nitride thereof, alloys thereof, or combinations thereof.

Referring to FIG. 1B, following the formation of the interconnect structure 106 and the connectors 108, the structure 100 illustrated in FIG. 1A is flipped upside down and mounted onto a carrier 112, the connectors 108 and the isolation layer 109 are attached (or adhered) onto a temporary adhesion layer 110 on the carrier 112, while a surface 102S of the substrate 102 is exposed. In other words, the temporary adhesion layer 110 assists the temporary attachment of the structure 100 on the carrier 112.

Referring to FIG. 1B and FIG. 1C, a thinning process TP1 is performed to the exposed surface 102S and a portion of the substrate 102 is removed until tops 104T (top ends) of the underlying TSVs 104 are revealed from the substrate 102, and forming a surface 102S′ of the substrate 102. In some embodiments, the thinning process includes a chemical mechanical polishing (CMP) process or an etching process, to remove the substrate 102 to reveal the tops 104T (top ends) of the TSVs 104. In some embodiments, the tops 104T (top ends) of the TSVs 104 are substantially level with one another and are level with the surface 102S′ of the substrate 102. Subsequently, an isolation layer 114 is formed on the substrate 102 over the TSVs 104 and a plurality of connectors 116 is formed in the isolation layer 114. In some embodiments, the isolation layer 109 or 114 may include a dielectric material such as silicon nitride, silicon oxide, silicon carbide, silicon oxynitride, silicon oxycarbide, a polymeric material such as benzocyclobutene (BCB), polyimide (PI), or polybenzoxazole (PBO), a low-K dielectric material such as phosphor-silicate glass (PSG), boro-phosph-silicate glass (BPSG), fluorosilicate glass (FSG), spin-on glass (SOG), combinations thereof, or the like. In some embodiments, the isolation layer 109 or 114 is formed using a suitable deposition process, such as chemical vapor deposition (CVD), spin-coating, or the like. In some embodiments, the connectors 116 are disposed on and connected with the TSVs 104. In some embodiments, the connectors 116 may include conductive posts, conductive pillars, conductive vias, or the like.

Referring to FIG. 1D, in a subsequent step, a redistribution layer (RDL) 118 is formed over the plurality of connectors 116, and electrically connected to the TSVs 104 through the plurality of connectors 116. The redistribution layer 118 includes a dielectric layer 1181 and conductive patterns 1182 embedded therein. The dielectric layer 1181 may be constituted by two or more dielectric layers, and the configurations of the conductive patterns 1182 may include routing lines, vias, pads or other designs according to routing requirements. In some embodiments, the conductive patterns 1182 includes bond pads 1183 for bonding or connection with other components or devices. The dielectric layer 1181 may be formed from a material selected from polyimide (PI), benzocyclobutene (BCB), polybenzooxazole (PBO), or any other suitable polymer-based dielectric material. The conductive patterns 1182 may be formed from a conductive material, including metals and/or metal alloys, such as copper, aluminum, nickel, titanium, alloys thereof, or combinations thereof. The formation of the redistribution layer 118 may include coating, CVD, physical vapor deposition (PVD), plating such as an electroplating process, lamination or combinations thereof.

Referring to FIG. 1D and FIG. 1E, a singulation process DL is performed to cut the structure 100 into individual electronic components 100a. In some embodiments, the singulation process involves a wafer dicing process with a rotating blade or a laser beam. In other words, the singulation process is or includes, for example, a laser cutting process, a mechanical dicing process, or other suitable processes.

Referring to FIG. 1E, the electronic component 100a includes the substrate 102 having a plurality of TSVs 104 penetrating there-through, the interconnect structure 106 disposed on a first side 102a of the substrate 102, and connectors 116 embedded in the isolation layer 114 and disposed at a second side 102b of the substrate 102. In some embodiments, the interconnect structure 106 and the connectors 116 are electrically connected with the TSVs 104 so as to establish electrical paths for both sides and provide double-sided electrical connectivity. In some embodiments, the redistribution layer 118 is disposed on the isolation layer 114 and the connectors 116 at the second side 102b of the substrate 102, opposite the first side 102a. In some embodiments, a plurality of connectors 108 is embedded in the isolation layer 109 and disposed on the interconnect structure 106.

FIG. 1F is a schematic cross-sectional view illustrating an exemplary structure of an electronic component 100b having double-sided connectivity in accordance with some embodiments of the present disclosure. In some embodiments, the process steps and materials used for forming the exemplary structure are similar to the process steps and materials described with reference to FIG. 1A-FIG. 1E and in the previous paragraphs, so the detailed descriptions thereof shall be omitted herein. Similar or substantially the same structural parts or elements may be labelled with similar or the same reference numbers as FIG. 1A through FIG. 1E, for illustration purposes.

Referring to FIG. 1F, the electronic component 100b includes a substrate 102 having a plurality of TSVs 104 penetrating there-through, the interconnect structure 106 disposed on a first side 102a of the substrate 102, and connectors 116 embedded in the isolation layer 114 and disposed at a second side 102b of the substrate 102. In some embodiments, the interconnect structure 106 and the connectors 116 are electrically connected with the TSVs 104 so as to establish electrical paths for both sides and provide double-sided electrical connectivity. In some embodiments, the redistribution layer 118 is disposed on the isolation layer 114 and the connectors 116 at the second side 102b of the substrate 102, opposite the first side 102a. In some embodiments, a plurality of connectors 108′ is disposed on the interconnect structure 106. Different from the previous embodiment, for the electronic component 100b, the connectors 108′ are or include conductive bumps such as micro-bumps, or metal posts with solder paste.

Through the formation of TSVs 104, the obtained electronic components 100a, 100b are capable of establishing electrical connection from both sides through the redistribution layer 118, TSVs 104, the interconnect structure 106 and connectors 108/108′, thus providing double-sided electrical connection (connectivity).

In some embodiments, the obtained electronic components 100a or 100b may be device dies including devices such as voltage regulators, transmitters, receivers, amplifiers, capacitors, inductors, power management integrated circuits (PMIC), or switches, combinations thereof. In some embodiments, electronic components 100a or 100b may be an integrated passive device (IPD) die. In some embodiments, electronic components 100a or 100b may function as a bridge die for interconnecting other adjacent semiconductor dies.

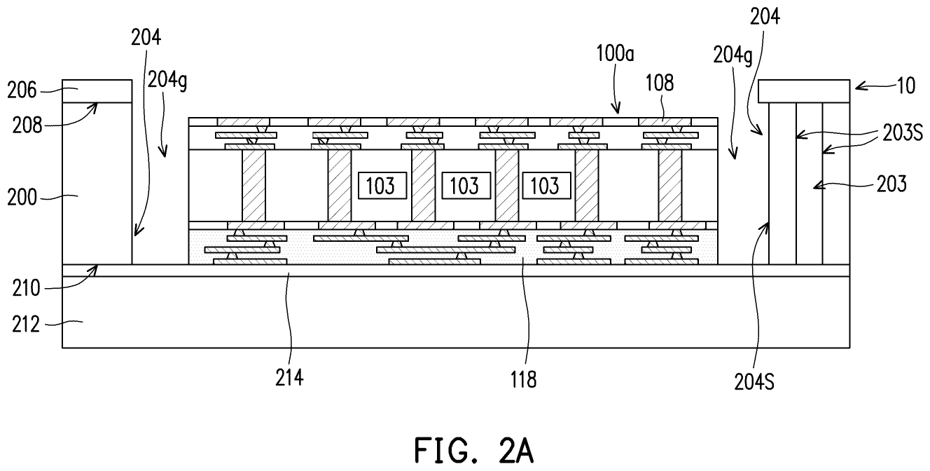

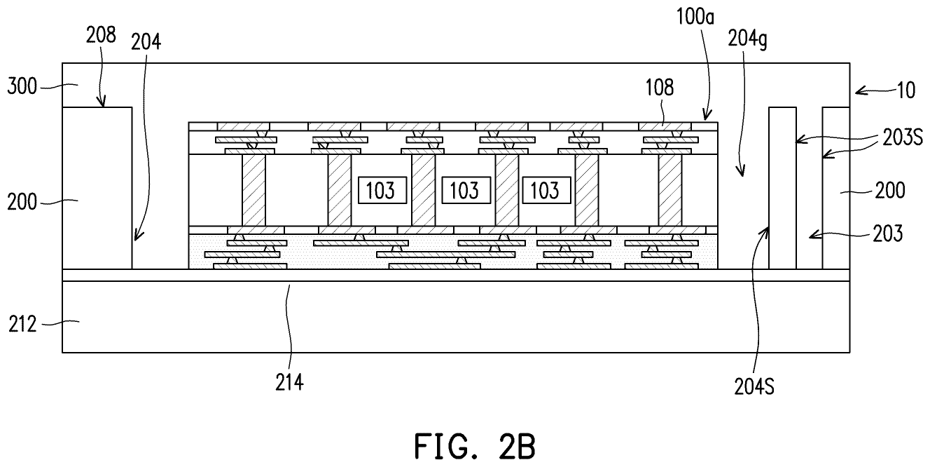

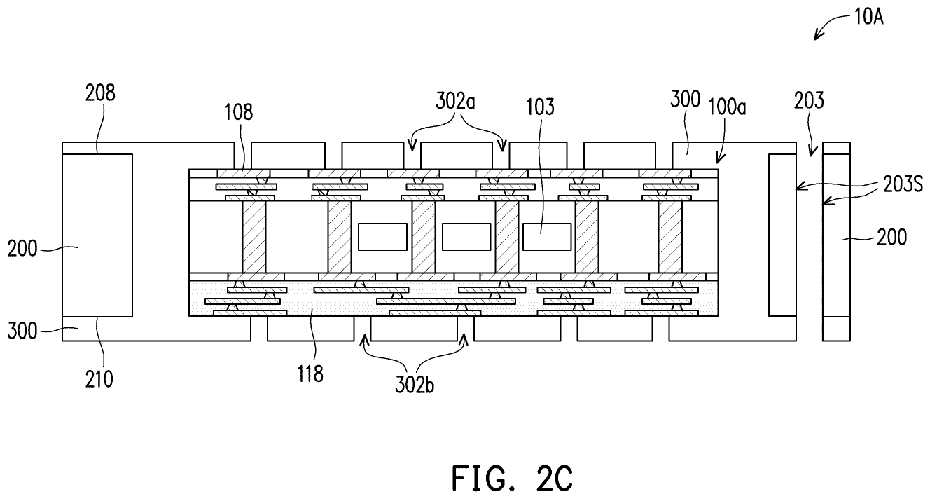

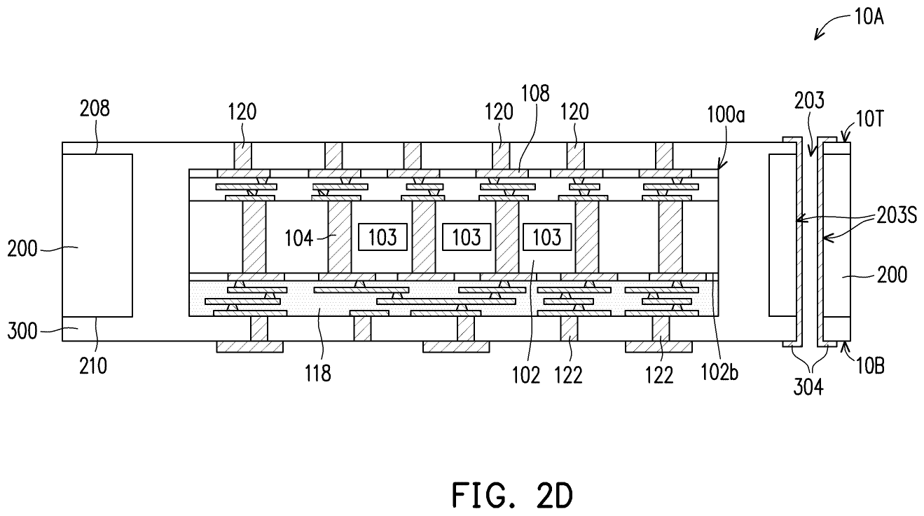

In some embodiment, the electronic component 100a, 100b may be mounted in or into a package substrate including a glass core layer to establish electrical connection with next-level devices or components. In some embodiments, a core layer 200 (as illustrated in FIG. 2A) may further include or formed with other types of device or electronic components therein, and the disclosure is not limited to the embodiments illustrated herein. In some embodiment, additional contact pads and joints may be formed over the individual electronic component 100a, 100b for joining with contacts of a package substrate.

FIG. 2A through FIG. 2D are schematic plane views illustrating intermediate stages of a method of forming a package substrate with an electronic component therein, in accordance with some embodiments of the present disclosure. The steps of encapsulating the as-described electronic component(s) 100a are described in subsequent steps of the processes as illustrated in FIG. 2A-FIG. 2D.

Referring to FIG. 2A, in some embodiments, at least one electronic components 100a as illustrated in FIG. 1E is provided within a package substrate 10. In some embodiments, the package substrate 10 includes a core layer 200 having multiple through holes 203 and a covering layer 206 thereon is provided on a temporary carrier 212. In some embodiment, the package substrate 10 may be adhered (attached) on the temporary carrier 212 through a temporary bonding layer 214 formed on the temporary carrier 212. In some embodiments, the temporary bonding layer 214 may include a release layer for facilitating the removal of the temporary carrier 212 in the subsequent process steps. The temporary carrier 212 may be a glass substrate, a metal plate, a plastic supporting board or the like, or any other suitable substrate materials may be used as long as the materials are able to withstand the subsequent steps of the process.

According to some embodiments, the core layer 200 of the package substrate 10 includes a glass layer, and the glass may be an amorphous solid. In some embodiments, the core layer 200 may be formed from a material selected from alkali glass, non-alkali glass, fused silica, pure silica, soda-lime glass, borosilicate glass, and aluminosilicate glass; however, the disclosure is not specifically limited thereto. It should be noted that glasses having alternative base materials (for example, fluoride glasses, phosphate glasses, chalcogen glasses, etc.) may also be employed. Further, any combination of other materials and additives may be combined with silica (or other base material) to form a glass having desired physical properties. Examples of these additives may further include magnesium, calcium, manganese, aluminum, lead, boron, iron, chromium, potassium, sulfur, and antimony, carbonates and/or oxides and other elements. The aforementioned glasses and additives are but a few examples of the many types of materials and material combinations that may be used for fabricating the core layer 200 of the present disclosure. In addition, the glass core layer 200 may include surface treatments and/or coatings to improve strength and/or durability, and the glass core layer 200 may be annealed to reduce internal stresses. In some embodiment, the glass material used for the core layer 200 does not include organic polymer materials. However, it should be understood that the glass according to some embodiments may include carbon as one of the material's constituents. For example, soda-lime glass, as well as numerous variations of this glass type, comprises carbon.

In one embodiment, the core layer 200 includes a single piece of glass. In other embodiments, the core layer 200 includes two or more glass sheets or multiple sections of glass joined together. In one embodiment, the covering layer 206 covers the through holes 203 and may be used to hold and secure adjacent glass sections in place, for subsequent processing. In some embodiment, the core layer 200 includes one or more cavities 204 extending from an upper surface 208 of the core layer 200, through the core layer 200 to an opposing lower surface 210 of the core layer 200.

Still referring to FIG. 2A, the individual electronic component(s) 100a (only one is shown) as illustrated in FIG. 1E is disposed into the cavity 204 of the core layer 200 and on the temporary carrier 212. In some embodiments, the prefabricated electronic components 100a may be picked and placed into the cavities 204 of the core layer 200. In some embodiments, the electronic component 100a is placed with the connectors 108 facing upward and the redistribution layer 118 facing the carrier 212.

In some embodiments, the core layer 200 may be fabricated to include one or more cavities 204, each cavity 204 accommodating at least one electronic component 100a (or 100b). In some embodiments, the cavities 204 are formed by a laser cutting process, a grinding process, a mechanical sawing process, or other suitable processes. Although the electronic component 100a is shown in FIG. 2A, the electronic components accommodated in the cavities 204 of the core layer 200 may include semiconductor structures or dies with single-sided electrical connection or semiconductor structures or die with double sided electrical connection. In some embodiments, the electronic component 100a is a device die including integrated passive devices (IPD).

According to some embodiments, the cavity 204 is formed with a size (length/width) larger than the accommodated electronic component 100a so that the electronic component 100a is spaced from the sidewalls 204S of the cavity 204 with gaps 204g existing there-between. It should be noted that the cavity 204 can be of any shape to accommodate the electronic components of interest, and may be formed with a rectangular shape for accommodating diced semiconductor dies. In an embodiment, the core layer 200 may have a thickness of between 50 μm to 1200 μm, and the electronic component 100a may have a thickness of between 30 μm to 600 μm, but the disclosure is not limited thereto. In some embodiments, the core layer 200 has a thickness larger than that of the electronic component 100a. The various dimensions of the cavity 204 may be adjusted according to the dimensions of the core layer 200 and electronic components 100a.

In some embodiments, as seen in FIG. 2A, the through holes 203 in the core layer 200 extend from the upper surface 208, through the core layer 200 and to the lower surface 210 of the core layer 200. Referring to FIG. 2A, sidewall surfaces 203S of the through hole 203 are shown to be substantially vertical sidewalls perpendicular to the lower surface 210 of the core layer 200. However, it is understood that slant sidewalls may be formed for the through holes 203. For example, the through hole 203 in the core layer 200 may be formed by imprinting, casting, laser drilling, etching, or any other suitable techniques, but the disclosure is not limited thereto. In some embodiments, critical dimensions of the TGVs may be in the range of 10 μm to 200 μm, and the average pitch of the through hole 203 may be in the range of 20 μm to 400 μm. However, the disclosure is not limited thereto.

Referring to FIG. 2A and FIG. 2B, in a subsequent step, the covering layer 206 disposed on the upper surface 208 of the core layer 200 is removed, and an insulating material 300 is disposed over the package substrate 10, filling into the cavities 204 and through holes 203, and in direct contact with the upper surface 208 of the core layer 200. In some embodiment, the through holes 203 and the gaps 204g between the electronic components 100a and the sidewalls 204S of the cavity 204 are filled by the insulating material 300. In some embodiments, the insulating material 300 fully covers the electronic component 100a located within the cavity 204 (covering the connectors 108 of the electronic component 100a), and fills up the gaps 204g between the electronic component 100a and the sidewall 204S of the cavity 204, in FIG. 2B. In some embodiments, the insulating material 300 may be formed of any suitable material, including polymeric materials, ceramic materials, plastics, composite materials, liquid crystals polymers (LCPs), epoxy laminates of fiberglass sheets, Prepreg, Ajinomoto build-up film (ABF), combination thereof, and the like. The formation of the insulating material 300 may include coating, deposition, lamination or combinations thereof. Later, the package substrate 10 including the core layer 200 and the electronic component 100a embedded within the cavity 204 is detached from the temporary carrier 212. It is understood that the formation of the insulating material 300 may be repeated to the other side of the core layer 200 while detaching from the temporary carrier 212, and the package substrate structure 10A is formed with the electronic component 100a encapsulated by the insulating material 300.

Referring to FIG. 2C, the package substrate structure 10A that includes the package substrate 10 and the electronic component 100a encapsulated by the insulating material 300 is patterned, so that the insulating material 300 covering both sides (covering the surfaces 208, 210) of the core layer 200 is partially removed to form a plurality of openings 302a, 302b in the insulating material 300, thereby exposing the underlying corresponding connectors 108 and the redistribution layer 118 of the electronic component 100a. In some embodiments, through the same patterning process or by a different drilling process, the insulating material 300 covering and inside the through holes 203 is removed to expose the sidewall surfaces 203S of the through holes 203. In some embodiments, the openings 302a, 302b expose the intended locations for the subsequently formed connectors 120, 122 (as illustrated in FIG. 2D).

Referring to FIG. 2D, in some embodiment, a metallic material (not shown) is formed over both sides 10T, 10B of the package substrate structure 10A and then patterned to form plated through hole structures 304 in the through holes 203. In some embodiments, connectors 120 and 122 are formed at both sides 10T, 10B of the package substrate structure 10A respectively formed onto the connectors 108 and the redistribution layer 118, exposed by the openings 302a and 302b. The first connectors 120 and second connectors 122 are electrically connected with the connectors 108 and the redistribution layer 118 of the electronic component 100a respectively, and are electrically connected with the device layers 103 and electrically connected with each other through TSVs 104. In some embodiments, the first and second connectors 120, 122 may include conductive posts, conductive bumps, conductive pillars, conductive vias, or the like. In some embodiment, as the core layer 200 is a glass core layer, the plated through hole structures 304 include through glass vias. In some embodiment, the plated through hole structures 304 penetrate through the package substrate structure 10A and are electrically conductive from both sides 10T, 10B of the package substrate structure 10A. In some embodiments, the plated through hole structures 304 are formed by plating or depositing the metallic material conformally along the sidewalls 203S of the through holes 203. In an embodiment, the plated through hole structures 304 are partially filled structures. In an embodiment, the plated through hole structures 304 are fully filled structures according to design or performance requirements. In an embodiment, the plated through hole structures 304 also include extension portions extending around both ends of the through holes 203 and extending over exposed surfaces of the insulating material 300. The metallic material of the plated through hole structures 304 includes metals, for example copper, tin, silver, gold, nickel, aluminum, and tungsten, as well as alloys of these metals.

Through the embedded electronic component with double-sided electrical connectivity (such as IPD dies or bridge dies), the area penalty caused by the plated through hole structures or through glass vias can be cased or lessened and the impedance of power delivery network can be mitigated.

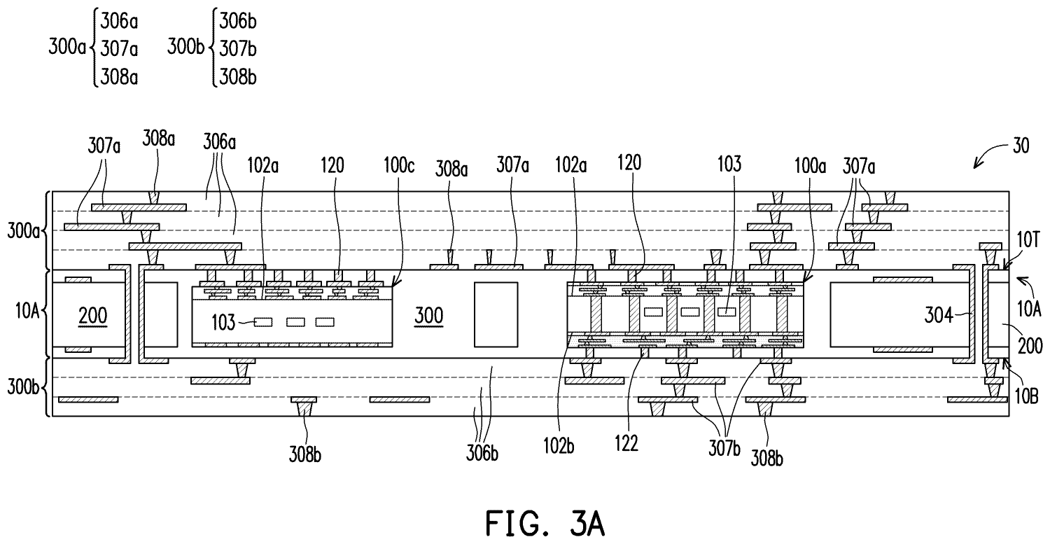

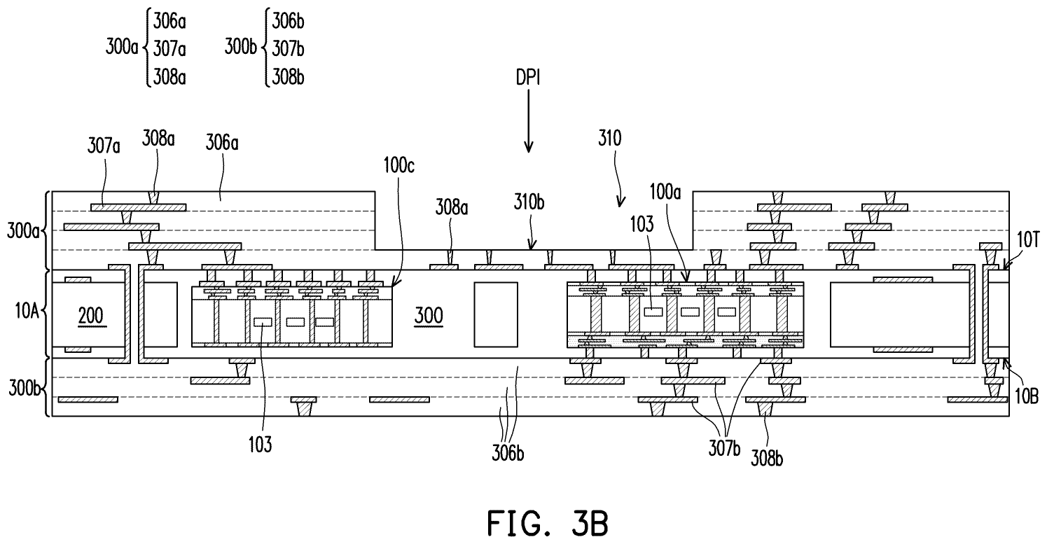

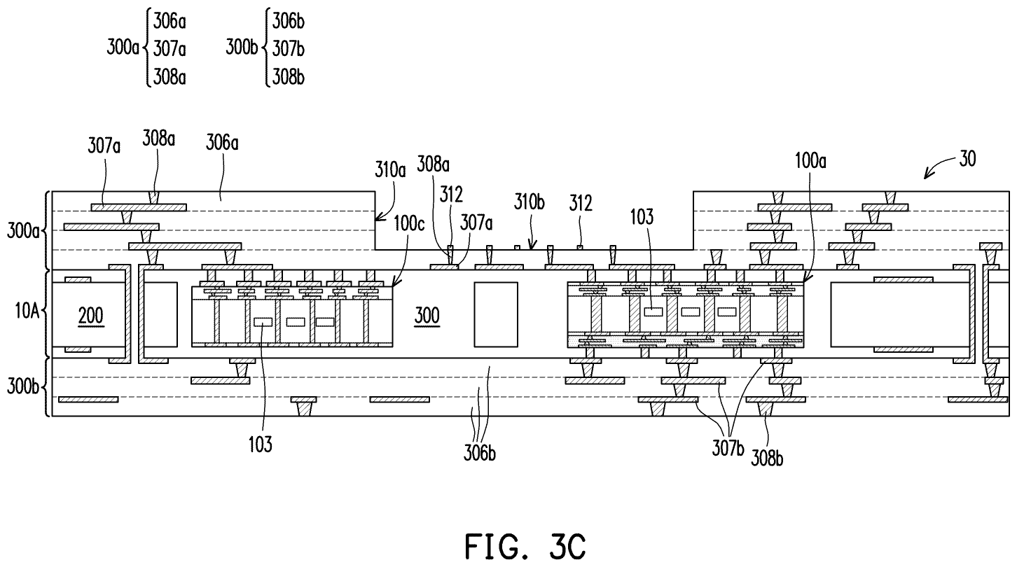

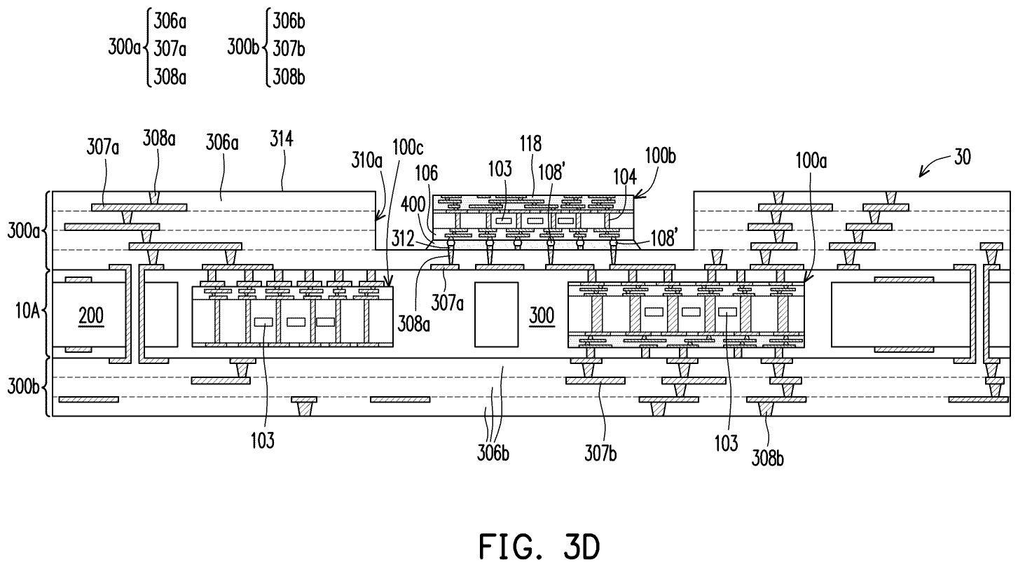

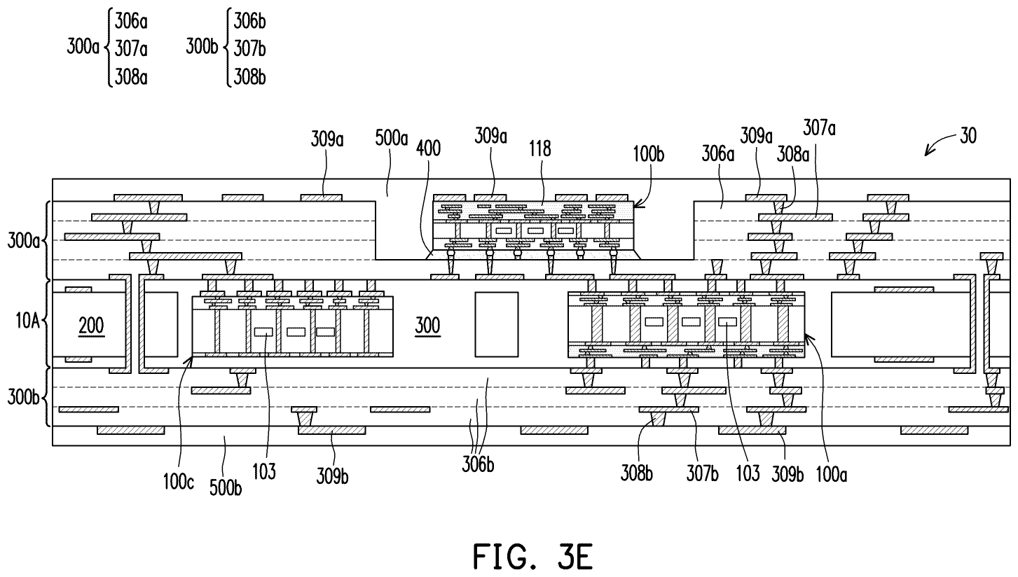

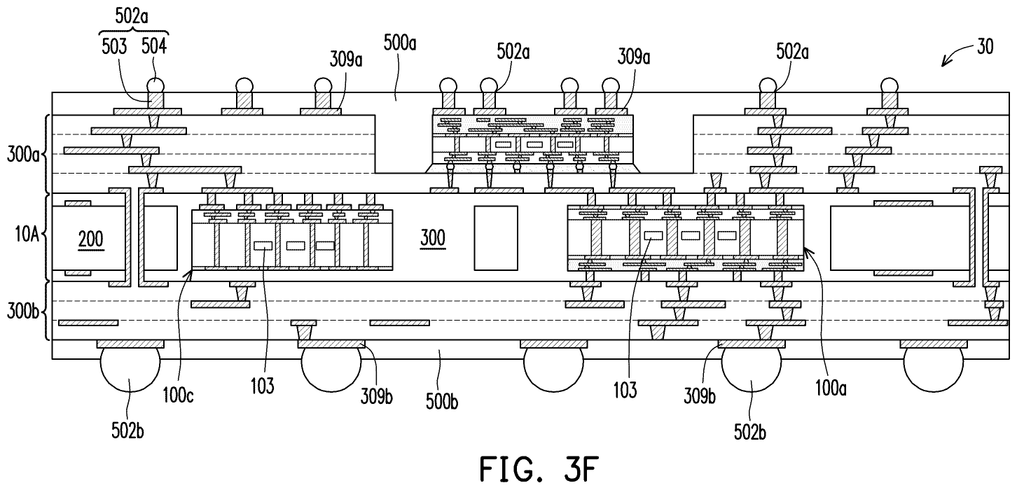

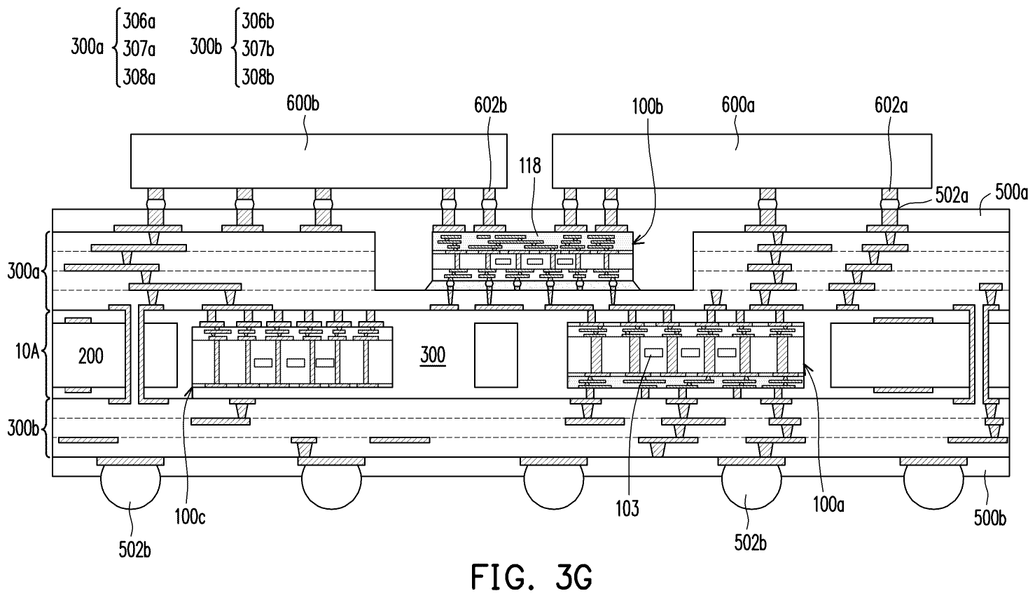

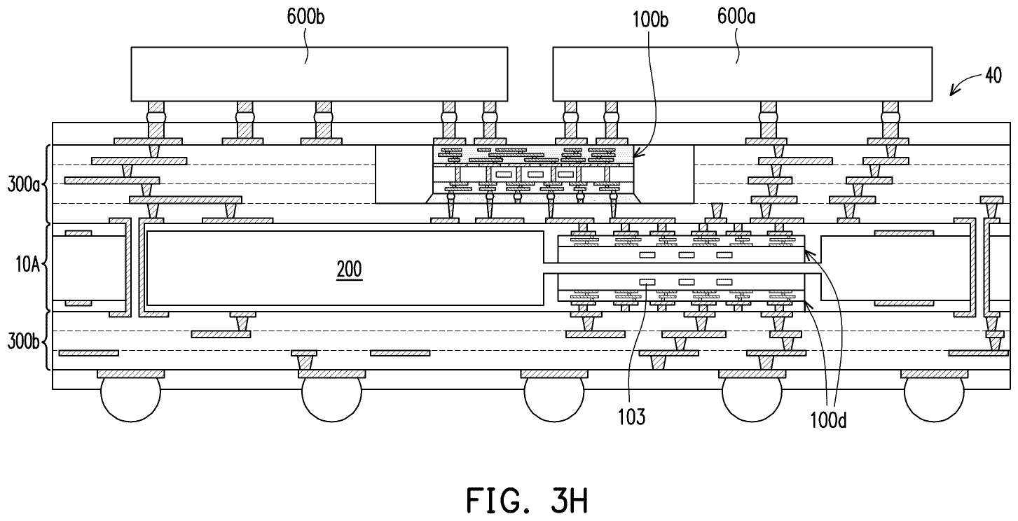

FIG. 3A through FIG. 3H are schematic cross-sectional views illustrating structures produced at various stages of a manufacturing process of a semiconductor package in accordance with some embodiments of the present disclosure. It is noted that the package substrate structure 10A as illustrated in FIG. 2D and electronic components similar to or the same as the electronic components 100a, 100b as illustrated in FIG. 1E, FIG. 1F may be used as parts of the component and elements in the structure presented in FIG. 3A through FIG. 3H, similar parts, layers and/or components may be labelled or denoted by the similar or the same reference numerals.

Referring to FIG. 3A, the package substrate structure 10A (as illustrated in FIG. 2D) is obtained, and build up structures 300a, 300b are formed respectively on opposing sides 10T, 10B of the package substrate structure 10A to form a stack package substrate structure 30. In some embodiments, the core layer 200 of the package substrate structure 10A is a glass core layer, including a single piece of glass or a plurality of glass sections. In some embodiments, as seen in FIG. 3A, an electronic component(s) 100a (only one is shown) as illustrated in FIG. 1E having double sided electrical connectivity is embedded in the package substrate structure 10A, and another electronic components(s) 100c (only one is shown) having single sided electrical connectivity is embedded in the package substrate structure 10A. In some embodiments, the electronic components(s) 100c having single sided electrical connectivity is similar to the electronic component 100a or 100b except for lacking the TSVs.

In an embodiment, the build up structure 300a, 300b disposed on opposing sides of the package substrate structure 10A are electrically connected with each other through the plated through hole structure 304. The first and second build up structure 300a, 300b respectively includes a stack insulating sub-layers 306a, metal layers 307a and vias 308a and a stack of insulating sub-layers 306b, metal layers 307b and vias 308b. For example, the metal layers 307a, 307b may include metal routing lines, pads or contacts, and the metal layer(s) 307a, 307b and the via(s) 308a, 308b embedded in the corresponding insulating sublayer(s) 306a, 306b are electrically interconnected to provide electrical connection for the build up structures 300a, 300b. In some embodiments, the insulating sub-layer(s) 306a, 306b may be any suitable material, including polymeric materials, ceramic materials, plastics, composite materials, liquid crystal polymers (LCPs), epoxy laminates of fiberglass sheets, Prepreg, a compound material of glass filler and resin including ABF, combinations thereof, or the like. In some embodiments, the insulating sub-layer(s) 306a, 306b may be formed by deposition, lamination, or any other suitable technique. In some embodiments, the metal layer(s) 307a, 307b may be an electrically conductive metal, for example, copper, aluminum, silver, or the like, and deposited by a plating process, including electroplating, or electroless plating. In some embodiments, the metal layer(s) 307a, 307b formed in the build up structure 300a, 300b may also be patterned to form in any number and configuration to facilitate routing of power and transmission of input/output (I/O) signals, and to route signals and power through the semiconductor package. It should be noted that the number of build up layers illustrated in FIG. 3A is for the sake of brevity, from the perspective of the manufacturing process, the build up structure 300a, 300b may constitute more or less build up layers, and the number and thickness of each build up layer may be adjusted according to design requirement. In the embodiment of FIG. 3A, the first and the second build up structures 300a, 300b are shown to have the same number of build up layers. However, the disclosure is not limited thereto. In some alternative embodiments, the number of build up layers on either side of the package substrate structure 10A may be asymmetrical.

In some embodiment, the electronic component 100a having double sided electrical connectivity, embedded within the core layer 200 includes one or more connectors 120, 122 disposed on the first side 102a and second side 102b of the electronic component 100a respectively, and the connectors 120, 122 are respectively electrically connected to the metal layers 307a, 307b of the multi-layered build up structures 300a, 300b. In embodiments, the electronic component 100c having single sided connectivity includes one or more connectors 120 disposed on the first side 102a of the electronic component 100c. The connectors 120 are arranged to be electrically connected to the metal layers 307a of the multi-layer first build up structure 300a, and to the semiconductor devices in the device layer 103.

Still referring to FIG. 3A, the package substrate structure 10A includes the insulating material 300 covering both sides of the core layer 200, and some insulating sub-layers 306a, 306b and some metal layers 307a, 307b are disposed directly on the insulating material 300. In some embodiments, the plated through hole structure 304 electrically connect the first and the second build up structures 300a, 300b disposed on the package substrate structure 10A through the metal layers 307a, 307b and vias 308a, 308b, in order to establish electrical connection and propagate electrical signals between the first and the second build up structures for double-sided electrical connectivity. In some embodiments, the insulating material 300 may be formed of the same material of the insulating sub-layers 306a, 306b of the build up structures 300a, 300b. In some embodiments, the insulating material 300 and the insulating sub-layers 306a, 306b of the build up structures 300a, 300b are formed of different materials.

Referring to FIG. 3B, in an embodiment, a recess 310 is formed in the first build up structure 300a, and the recess 310 may be used for accommodating an electronic component (bridge die) 100b in the subsequent step (as shown in FIG. 3D). In some embodiments, a patterning process DPI is performed to form the recess 310 in the first build up structure 300a. In some embodiments, the patterning process DPI includes, for example, an etching process, a milling process, or laser removal techniques, or a combination thereof. In an embodiment, the recess 310 may be formed by using, e.g., a laser drilling process. The recess 310 may extend downwardly toward the upper surface 10T of the package substrate structure 10A but do not extend through the whole stack of the first build up structure 300a. After the formation of the recess 310, some vias 308a on the metal layers 307a are exposed from a bottom surface 310b of the recess 310. The depth of the recess 310 is equal or greater than the thickness of the electronic component (bridge die) 100b to be formed in the subsequent step (as illustrated in FIG. 3D).

Referring to FIG. 3C and FIG. 3D, micro-connectors 312 are formed on the exposed vias 308a over the bottom surface 310b of the recess 310. In some embodiments, the micro-connectors 312 include micro-bumps or metallic pillars, and are electrically connected to the underlying metal layers 307a of the first build up structure 300a through the vias 308a. Subsequently, an electronic component 100b is disposed into the recess 310. In some embodiment, the electronic component 100b functions as a bridge die is picked and placed into the recess 310 in the first build up structure 300a.

In some embodiment, the electronic component 100b is similar to or the same as the electronic component 100b illustrated in FIG. 1F, the process steps used for forming the electronic component (bridge die) 100b are similar to the process steps described with reference to FIG. 1F, and in the previous paragraphs, so the detailed description shall be omitted herein. Similar or substantially the same structural parts or elements may be labelled with similar or same reference numbers as FIG. 1F, for illustration purpose. In some embodiments, the electronic component (bridge die) 100b may include active components (e.g., transistors, or the like), and optionally passive components (e.g., resistors, capacitors, inductors, or the like) formed therein. In some embodiments, the electronic component (bridge die) 100b is bonded to the first build up structure 300a.

Referring to FIG. 3D, the electronic component (bridge die) 100b is placed with the redistribution layer 118 facing upwards and the connectors 108′ (e.g., micro bumps) of the electronic component (bridge die) 100b facing the electronic component(s) 100a, 100c. In some embodiments, the connectors 108′ are electrically connected with the redistribution layer 118 of the electronic component (bridge die) 100b through the TSVs 104, and are electrically connected with the semiconductor devices in the device layers 103 of the electronic component (bridge die) 100b. In some embodiment, the connectors 108′ are bonded with the micro-connectors 312 and the vias 308a by a reflow process, and the electronic component 100b is electrically connected to the first build up structure 300a, and electrically connected to the electrical component(s) 100a, 100c through the first build up structure 300a. In some embodiment, the redistribution layer 118 of the electronic component (bridge die) 100b may be electrically connected to a corresponding terminal on a semiconductor die or a next level substrate or component disposed over the electronic component (bridge die) 100b and first build up structure 300a (as illustrated in FIG. 3E through FIG. 3G of the subsequent process steps).

In some embodiment, as illustrated in FIG. 3D, a span of the electronic component (bridge die) 100b is smaller than a span of the recess 310, and a top surface of the redistribution layer 118 of the electronic component (bridge die) 100b is lower than a top-most surface 314 of the first build up structure 300a. In other words, the depth of the recess 310 may be greater than the thickness of the electronic component (bridge die) 100b, thereby allowing the electronic component (bridge die) 100b to be entirely accommodated within the first build up structure 300a, leaving a void between recess side walls 310a and the electronic component (bridge die) 100b. An underfill layer 400 may be formed between the interconnect structure 106 of the electronic component (bridge die) 100b and the first build up structure 300a, and laterally wrapping around the bonded structures of the connectors 108′ of the electronic component (bridge die) 100b and the micro-connectors 312 disposed on the first build up structure 300a. The underfill 400 at least fills gaps between the electronic component (bridge die) 100b and the first build up structure 300a and secure the bonding there-between. In some embodiments, the underfill 400 may include epoxy resin. The underfill 400 may be formed by underfill dispensing, a capillary flow process, or any other suitable method. In some embodiments, the underfill 400 is dispensed into the gaps between the electronic component (bridge die) 100b and a bottom surface 310b of the recess 310, using for example, a dispensing needle or other suitable dispensing tools, and then cured to harden. The underfill 400 enhances the bonding strength between the electronic component (bridge die) 100b and the first build up structure 300a.

Although FIG. 3A through FIG. 3D illustrated that the electronic component(s) 100a, 100c are embedded in the package substrate structure 10A prior to the placement of the electronic component (bridge die) 100b, the disclosure is not limited thereto.

Referring to FIG. 3E, after the underfill 400 is formed, covering layers 500a, 500b are formed over the first and second build up structures 300a, 300b respectively, covering the first and second build up structures 300a, 300b and the electronic component (bridge die) 100b. In some embodiments, the formation of the covering layer 500a involves forming an insulating material (not shown) between the electronic component (bridge die) 100b and first build up structure 300a, filling into the recess 310 to fill the void(s) between the electronic component (bridge die) 100b and the first build up structure 300a and wrapping around the electronic component (bridge die) 100b and underfill 400. Also, the covering layer 500a is formed to cover the first build up structure 300a and the electronic component (bridge die) 100b. In some embodiments, the insulating material may be formed by lamination or coating, and the insulating material may include one or more polymeric materials, ceramic materials, plastics, composite materials, liquid crystal polymers (LCPs), epoxy laminates of fiberglass sheets, Prepreg, a compound material of glass filler and resin including ABF, combinations thereof. In some embodiments, the formation of the covering layer 500b involves forming an insulating material (not shown) over the second build up structure 300b to fully cover the second build up structure 300b. In some embodiments, conductive contact 309a, 309b are formed respectively on the first build up structure 300a and the second build up structure 300b and are embedded respectively in the covering layers 500a, 500b. In some embodiments, the covering layers 500a, 500b include solder resist layers over the conductive contacts 309a, 309b.

Referring to FIG. 3F, in the next step, the covering layers 500a, 500b are patterned to form openings at the locations corresponding to the conductive contacts 309a, 309b, thereby exposing surfaces of the conductive contacts 309a, 309b. Thereafter, conductive connectors 502a, 502b are respectively formed on the covering layers 500a, 500b within the openings exposing the conductive contacts 309a, 309b. In some embodiments, the conductive connectors 502a include micro bumps, copper bumps, controlled collapse chip connection (C4) bump, or the like. In one embodiment, the conductive connectors 502a include copper posts 503 and solder joints 504. In some embodiments, the conductive connectors 502b include any suitable types of structure capable of forming an electrical connection with a corresponding component, including solder bumps, controlled collapse chip connection (C4) bump, solder balls or the like. In some embodiment, through the conductive connectors 502a, 502b, the plated through hole structures 304 and the first and second buildup structures 300a, 300b, double-sided electrical connection is provided for the structure 30 to be electrically connected to a corresponding terminal on a semiconductor die or a next level substrate or component

Referring to FIG. 3G, in some embodiment, semiconductor dies 600a, 600b are mounted onto the covering layer 500a and are electrically connected to the conductive connectors 502a on the first build up structure 300a. In some embodiments, the first and the second build up structure 300a, 300b may facilitate the delivery of power and transmission of input/output (I/O) signals between the semiconductor dies 600a, 600b and the package substrate structure 30.

As illustrated in FIG. 3G, the semiconductor dies 600a, 600b are bonded to the conductive connectors 502a through the respective conductive terminals 602a, 602b of the semiconductor dies 600a, 600b. For example, the conductive terminals 602a, 602b include copper pillars, stud bumps, or the like. In one embodiment, the conductive terminals 602a, 602b of the semiconductor dies 600a, 600b are bonded with the conductive connectors 502a formed on the first build up structure 300a via a reflow process. Alternatively, the semiconductor die(s) 600a, 600b may be attached onto the first build up structure 300a by a layer of die attach adhesive, and a plurality of wire bonds may be formed between the semiconductor die 600a, 600b and the first build up structure 300a. Even though one first semiconductor die 600a and one second semiconductor die 600b are shown in FIG. 3G, it is understood that a plurality of semiconductor dies 600a and a plurality of semiconductor dies 600b may be bonded, and the number of the dies used in the semiconductor package is not limited by the embodiments herein. Each one of the semiconductor dies 600a, 600b may respectively be or include a logic die, such as a central processing unit (CPU) die, a graphic processing unit (GPU) die, a micro control unit (MCU) die, an input-output (I/O) die, a baseband (BB) die, or an application processor (AP) die. In an embodiment, at least one of the first semiconductor die 600a include a system-on-chip (SoC) die, and at least one of the second semiconductor dies 600b include a memory die such as a high-bandwidth-memory (HBM) die. In some embodiments, the semiconductor dies 600a, 600b may be the same type of dies or perform the same functions. In other embodiments, the semiconductor dies 600a, 600b may be different types of dies or perform different functions. It is understood that the semiconductor dies 600a, 600b are or include device dies and semiconductor devices are formed within the semiconductor dies 600a, 600b.

In some embodiments, the first semiconductor die 600a is electrically connected to the second semiconductor die 600b through the electronic component (bridge die) 100b. For example, the signal generated from a semiconductor device formed in the first semiconductor die 600a may be transmitted through or processed by a semiconductor device in the electronic component (bridge die) 100b, and then transmitted to a semiconductor device formed in the second semiconductor die 600b through the conductive connectors 502a and the conductive terminals 602a, 602b of the first and the second semiconductor dies 600a. In some embodiments, the electronic component (bridge die) 100b functions to electrically connect the first semiconductor die 600a and the second semiconductor die 600b and provide an effective electrical connection path between the first semiconductor die 600a and the second semiconductor die 600b.

Referring to FIG. 3H, the structure 40 is similar to the structure 30 illustrated in FIG. 3G except that two electronic components 100d are provided and embedded inside the cavity of the core layer 200. In some embodiments, the electronic component 100d is similar to the electronic component 100c and is an electronic component with single-sided electrical connectivity. In FIG. 3H, the package substrate structure 10A may include multiple cavities of the same sizes or varying sizes and dimensions, arranged in a linear or stacked up manner to accommodate multiple electronic components having single- or double-sided electrical connectivity. The configuration shown in FIG. 3H merely serves as an exemplary illustration. In an embodiment, the two electronic components 100d having single-side electrical connectivity are accommodated in the two facing cavities separately in a stacked up manner. However, the disclosure is not limited thereto. Multiple cavities may be formed in various orientation across the core layer to accommodate a variety of different electronic components in the package substrate structure 10A.

Through the incorporation of the glass core layer, better flatness and less warpage can be achieved for the package substrate structure. Also, lower dielectric loss, fine L/S features and better routability can be accomplished through the usage of rigid glass core substrate structure.

In accordance with some embodiments of the disclosure, a package structure includes a core substrate. The package structure includes a build up structure disposed on the core substrate. The build up structure includes a recess in the build up structure. The package structure includes a semiconductor die disposed on the build up structure and over the core substrate. The package structure includes a bridge die disposed in the recess of the build up structure and between the semiconductor die and the core substrate. The bridge die includes first connectors and second connectors respectively disposed on two opposing surfaces of the bridge die and conductive through vias penetrating the bridge die and electrically connected with the first and second connectors. The bridge die is electrically connected with the semiconductor die and the core substrate respectively through the first connectors and second connectors. The core substrate includes a glass core layer, and through glass vias penetrating through the core substrate. The package structure includes an electronic component disposed in a cavity of the glass core layer of the core substrate. The electronic component is electrically connected with the bridge die through the second connectors and the build up structure. The electronic component includes a semiconductor substrate and through semiconductor vias. The semiconductor die is electrically connected with the electronic component through the bridge die, the build up structure and the core substrate. The package structure includes another electronic component embedded in the core substrate. The another electronic component is electrically connected with the semiconductor die through the core substrate and the build up structure. The package structure includes another semiconductor die disposed on the build up structure over the core substrate and beside the semiconductor die. The another semiconductor die is electrically connected with the semiconductor die through the bridge die.

In accordance with some embodiments of the disclosure, a package structure includes a substrate comprising a glass core layer. The glass core layer includes a cavity extending through the glass core layer. The package structure includes a first build up structure and a second build up structure disposed on an upper surface and a lower surface of the substrate respectively. The package structure includes a bridge die embedded in the first build up structure. The package structure includes a first semiconductor die and a second semiconductor die disposed over the bridge die and disposed on the first build up structure. The first semiconductor die is electrically connected with the second semiconductor die through the bridge die. The package structure includes an electronic component embedded within the cavity of the glass core layer. The electronic component is electrically connected to the first and the second semiconductor dies through the bridge die. A thickness of the glass core layer is greater than a thickness of the electronic component. The substrate includes a through glass via extending from the upper surface to the lower surface of the substrate and penetrating through the glass core layer. The through glass via comprises a plated through hole structure, and the through glass via is electrically connected with the first and the second build up structures. The bridge die includes a semiconductor substrate, first connectors disposed on a first side of the semiconductor substrate, through substrate vias (TSVs) extending through the semiconductor substrate and electrically connected with the first connectors, a redistribution structure disposed on a second side of the semiconductor substrate opposing the first side and electrically connected to the TSVs; and second connectors disposed on the redistribution structure. The second connectors and the semiconductor substrate are respectively located on opposite sides of the redistribution structure. The first and second build up structures include electrically interconnected metal layers sandwiched between insulating layers. The bridge die is electrically connected with the first and second semiconductor dies through the second connectors and electrically connected with the electronic component through the first connectors and the metal layers of the first build up structure. The package structure includes solder resist layers disposed on outermost surfaces of the first and second build up structures, and conductive terminals disposed on the solder resist layers, wherein the conductive terminals on the first and the second build up structure are electrically connected with the first and second semiconductor dies and electrically connected with the electronic component.

In accordance with some alternative embodiments of the disclosure, a method of manufacturing a package structure, includes providing a substrate including a glass core layer with a cavity extending through the glass core layer, embedding an electronic component in the cavity of the glass core layer, forming a first build up structure and a second build up structure on an upper surface and a lower surface opposite to the upper surface of the substrate, embedding a bridge die in the first build up structure. The bridge die is electrically connected to the core layer through the first build up structure formed on the upper surface of the core layer. The method of manufacturing a package structure includes providing and bonding a first semiconductor die and a second semiconductor die onto the first build up structure. The electronic component is electrically connected to the first and the second semiconductor dies through the bridge die. The method of embedding the electronic component in the glass core layer includes patterning the glass core layer to form the cavity in the glass core layer, disposing the electronic component in the cavity, and applying an insulating material layer onto the glass core layer to encapsulate the electronic component and fully cover the glass core layer. The method of manufacturing a package structure includes forming a through glass via extending from the upper surface to the lower surface of the substrate and penetrating through the glass core layer. The method of forming a through glass via includes forming a plated through hole structure. The method of manufacturing a package structure includes forming solder resist layers disposed on outermost surfaces of the first and second build up structures, and forming conductive terminals on the solder resist layers. The conductive terminals on the first and the second build up structure are electrically connected with the first and second semiconductor dies and electrically connected with the electronic component.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A package structure, comprising:
a core substrate,
a build up structure disposed on the core substrate, wherein the build up structure includes a recess in the build up structure;
a semiconductor die, disposed on the build up structure and over the core substrate;
a bridge die, disposed in the recess of the build up structure and between the semiconductor die and the core substrate, wherein the bridge die includes first connectors and second connectors respectively disposed on two opposing surfaces of the bridge die and conductive through vias penetrating the bridge die and electrically connected with the first and second connectors, and the bridge die is electrically connected with the semiconductor die and the core substrate respectively through the first connectors and second connectors.

2. The package structure according to claim 1, wherein the core substrate includes a glass core layer, and through glass vias penetrating through the core substrate.

3. The package structure according to claim 2, further comprising an electronic component disposed in a cavity of the glass core layer of the core substrate, wherein the electronic component is electrically connected with the bridge die through the second connectors and the build up structure.

4. The package structure according to claim 3, wherein the electronic component includes a semiconductor substrate and through semiconductor vias.

5. The package structure according to claim 3, wherein the semiconductor die is electrically connected with the electronic component through the bridge die, the build up structure and the core substrate.

6. The package structure according to claim 3, further comprising another electronic component embedded in the core substrate, wherein the another electronic component is electrically connected with the semiconductor die through the core substrate and the build up structure.

7. The package structure according to claim 1, further comprising another semiconductor die disposed on the build up structure over the core substrate and beside the semiconductor die, wherein the another semiconductor die is electrically connected with the semiconductor die through the bridge die.

8. A package structure, comprising:
a substrate comprising a glass core layer, wherein the glass core layer includes a cavity extending through the glass core layer;
a first build up structure and a second build up structure disposed on an upper surface and a lower surface of the substrate respectively;
a bridge die embedded in the first build up structure;
a first semiconductor die and a second semiconductor die disposed over the bridge die and disposed on the first build up structure, wherein the first semiconductor die is electrically connected with the second semiconductor die through the bridge die; and
an electronic component embedded within the cavity of the glass core layer, wherein the electronic component is electrically connected to the first and the second semiconductor dies through the bridge die.

9. The package structure according to claim 8, wherein a thickness of the glass core layer is greater than a thickness of the electronic component.

10. The package structure according to claim 8, wherein the substrate includes a through glass via extending from the upper surface to the lower surface of the substrate and penetrating through the glass core layer.

11. The package structure according to claim 10, wherein the through glass via comprises a plated through hole structure, and the through glass via is electrically connected with the first and the second build up structures.

12. The package structure according to claim 8, wherein the bridge die comprises:
a semiconductor substrate;
first connectors disposed on a first side of the semiconductor substrate;
through substrate vias (TSVs) extending through the semiconductor substrate and electrically connected with the first connectors;
a redistribution structure disposed on a second side of the semiconductor substrate opposing the first side and electrically connected to the TSVs; and
second connectors disposed on the redistribution structure, wherein the second connectors and the semiconductor substrate are respectively located on opposite sides of the redistribution structure.

13. The package structure according to claim 12, wherein the first and second build up structures include electrically interconnected metal layers sandwiched between insulating layers.

14. The package structure according to claim 13, wherein the bridge die is electrically connected with the first and second semiconductor dies through the second connectors and electrically connected with the electronic component through the first connectors and the metal layers of the first build up structure.

15. The package structure according to claim 8, further comprising solder resist layers disposed on outermost surfaces of the first and second build up structures, and conductive terminals disposed on the solder resist layers, wherein the conductive terminals on the first and the second build up structure are electrically connected with the first and second semiconductor dies and electrically connected with the electronic component.

16. A method of manufacturing a package structure, comprising:
providing a substrate including a glass core layer with a cavity extending through the glass core layer;
embedding an electronic component in the cavity of the glass core layer;
forming a first build up structure and a second build up structure on an upper surface and a lower surface opposite to the upper surface of the substrate;
embedding a bridge die in the first build up structure, wherein the bridge die is electrically connected to the core layer through the first build up structure formed on the upper surface of the core layer; and
providing and bonding a first semiconductor die and a second semiconductor die onto the first build up structure, wherein the electronic component is electrically connected to the first and the second semiconductor dies through the bridge die.

17. The method according to claim 16, wherein embedding the electronic component in the glass core layer comprises:
patterning the glass core layer to form the cavity in the glass core layer;
disposing the electronic component in the cavity; and
applying an insulating material layer onto the glass core layer to encapsulate the electronic component and fully cover the glass core layer.

18. The method according to claim 17, further comprising forming a through glass via extending from the upper surface to the lower surface of the substrate and penetrating through the glass core layer.

19. The method according to claim 18, wherein forming a through glass via includes forming a plated through hole structure.

20. The method according to claim 16, further comprising forming solder resist layers disposed on outermost surfaces of the first and second build up structures, and forming conductive terminals on the solder resist layers, wherein the conductive terminals on the first and the second build up structure are electrically connected with the first and second semiconductor dies and electrically connected with the electronic component.
